(19) United States
(12) Patent Application Publication
(10) Pub. No.: US 2012/0074954 A1
(43) Pub. Date: Mar. 29, 2012

(54) ELECTRICAL CONNECTOR WITH CORROSION PREVENTION

(75) Inventors: Peter Dirk JAEGER, BP Dussen (NL); Emmanuel LANCELOT, Agen (FR); Jacobus Nicholaas TUIN, Best (NL)

(73) Assignees: TYCO ELECTRONICS FRANCE SAS, Pontoise (FR); TYCO ELECTRONICS NEDERLAND BV, S-Hertogenbosch (NL)

(21) Appl. No.: 13/246,119

(22) Filed: Sep. 27, 2011

(30) Foreign Application Priority Data
Sep. 28, 2010 (EP) 10290511.4

(51) Int. Cl. G01R 31/04

(52) U.S. Cl. 324/538

(57) ABSTRACT

The present invention relates to an electrical connector with at least one electrical contact for electrically contacting a corresponding mating connector. In particular, the present invention deals with connectors having a plug detecting unit for detecting a mated state of the connector and the mating connector. The present invention further relates to a corresponding method for detecting a mated state. Said connector comprises a plug detecting unit for detecting a mated state of the connector and the mating connector, wherein said plug detecting unit is operable to check the mated state by means of an intermittent test signal. Alternatively or additionally, the surfaces of first and second electrical contacts are covered with materials having a different oxidation potential, wherein a positive voltage of the test signal is applied to the electrical contact having the higher oxidation potential compared to the other electrical contact.

### BACKGROUND

The present invention relates to an electrical connector with at least one electrical contact for electrically contacting a corresponding mating connector. In particular, the present invention deals with connectors having a plug detecting unit for detecting a mated state of the connector and the mating connector. The present invention further relates to a corresponding method for detecting a mated state.

Generally, the present invention relates to electrical connectors for use with handheld cellular telephone units, and more particularly to a system connector that incorporates electrical contacts directly into the housing of a telephone in a manner such that the connector is sealed with respect to the external environment.

System connectors associated with cellular telephones are used to establish and maintain electrical connection between the internal circuitry of the telephone and an external electrical circuit or device. Examples of such external devices and connection requirements are battery charging equipment, base or docking stations typically employed in automobiles to permit hands free operation of the cellular telephone unit, and headsets. Historically, such system connectors presented openings or pathways for water and debris to freely enter the interior compartment of the telephone. Typically, these penetration pathways are present in the telephone unit because there are several separate components, including a printed circuit board, a structural frame member, and a housing enclosure that must be assembled, none of which are sealed prior to assembly. As such, system connectors are generally comprised of separate pieces that are either soldered directly to the printed board or are pressed onto the printed circuit board with the housing and the frame aligning around them.

Recent developments now arrange the electric contacts of the connector in a housing which is sealed against the inner elements of the telephone at least partly and enough to fulfill the requirements for a splash proof device.

In order to avoid the formation of short circuits and damages to the interior circuitry, the electrical connector may be shut down as long as no mating connector is inserted, and may only be carrying operational signals, such as audio/video signals or a connection to a battery, when the mating connector is inserted.

To this end, a plug detecting unit is provided which detects the presence of the mating connector.

However, the monitoring whether the mating connector is inserted or not, involves an electric potential present at the at least one electrical contact. Consequently, in the presence of humidity, such a constant voltage will lead to a galvanic process that results in quick and serious corrosion of the contact.

Known waterproof connectors for mobile telephones use a plating of two micrometer gold to reach the durability and sea water emersion requirement. The mobile phone market in general requires reliable connections for charging and accessories, but because of price pressure, no such thick noble platings can be economically used. This means that the gold flash over nickel contacts of conventional connectors will slowly degrade during use because of regular mating in combination of dust, humidity, perspiration and sea water and, furthermore, the gold flash is not able to cover the nickel contact pore free.

The problem underlying the present invention is to provide an electrical connector which reduces corrosion to a level that leads to a sufficiently long product life of the device where the connector is built in.

### SUMMARY

This problem is solved by a connector and a method for detecting a mated state of an electrical connector and a mating connector, according to the independent claims. Advantageous embodiments of the present invention are the subject matter of the dependent claims.

The invention is based on the idea that with conventional connectors where all potentials are shut down during a standby mode, the test signal itself, which has to be applied in order to detect that a plug has been inserted into the connector, causes a potential that leads to significant corrosion of the contacts. The inventors have recognized that this test signal has to be modified to diminish the corrosion to a degree that no problems will occur until the specified product life ends. Two different approaches are proposed, which can be applied separately or in combination:

Firstly, an electrical connector can have a plug detecting unit which is operable to check the mated state between the connector and the mating connector by means of an intermittent test signal, instead of the continuous test signals of conventional connector systems. By applying a short duration pulse sensing instead of a continuous voltage test signal, the corrosion speed may significantly be reduced. For instance, by replacing a constant voltage difference over any of the contacts of the input output connector by a short low voltage pulse of one millisecond at one second intervals of 1.8 volts, a reduction by a factor of one 1000 is achieved. Such a pulse-wise check if a plug is inserted will not prevent corrosion one hundred percent, but will delay the corrosion process significantly. The target has to be to postpone serious corrosion until after the product life ends.

The idea according to the present invention can be applied to any connector having a voltage difference over any of the contacts used in a condition which can cause contact degradation by ion migration.

The second idea which is proposed according to the present invention takes advantage of the fact that the occurring electrochemical corrosion depends on the oxidation potential of the materials involved. As generally known, corrosion is a degradation of metals as a result of electrochemical activity and requires an anode and a cathode in order to occur.

The anode is the metal, or site, with a higher potential to oxidize, that is to lose electrons. On the other hand, the cathode is the metal, or site, with a higher potential for reduction, that is gaining of electrons. In other words, the cathode has a lower potential to oxidize than the anode. The measure of a material to oxidize, or to lose electrons, is known as its oxidation potential. A difference between the oxidation potentials of two metals can lead to corrosion that will consume the metal that is more anodic.

Of course, two other factors are needed for corrosion, namely electrical connection between the two metals having the oxidation potential difference and the presence of an electrolyte such as water to conduct ions between them. The standard oxidation potential value is a measure to determine the tendency of a metal to become a cathode or an anode with respect to another metal for corrosion to occur.

Starting from this physical principle, the present invention is based on the idea that the electrical contact, which is carrying the test signal and a second reference contact, are consisting of, or are covered with, materials having a different oxidation potential. By applying a positive voltage to the electrical contact that has the higher oxidation potential compared to the other contact, corrosion due to the test signal can be delayed. For instance, the positive voltage may be applied to a gold contact having an oxidation potential of +1.50 V and ground potential may be applied to a nickel electrode having an oxidation potential of −0.25 V.

Of course, also other material combinations and different alloys may be used, as long as the electrode having the surface with the higher oxidation potential, that is, the metal with the higher nobility, or noble metal character, is connected to the positive voltage with respect to the other electrode. Consequently, by using gold plating on the externally plus charged contact and a nickel plating on the negative charged contacts, the corrosion rate of the nickel plated contact is decreased. The plus side is protected by the higher nobility of the gold. Thus, flash gold plated contacts may be used for splash or seawater proof connectors in the field of any handheld mobile devices such as smart phones, navigation equipment, cameras etc.

The intermittent test signal according to the present invention may comprise pulses having the form of a square wave signal or a sawtooth signal. Other suitable signal forms are, of course, also suitable. Furthermore, the polarity of the intermittent test signal may be chosen to be positive, negative or alternating.

A particularly effective reduction of corrosion speed may be achieved by choosing the intermittent test signal in a way that high potential phases and low potential phases alternate, wherein the high potential phases have a shorter duration than the low potential phases. High potential in the present context may preferably amount to 1.8 volt, whereas the low potential signifies 0 V. Other values can of course be chosen as required.

The test signal and the electrode configuration, according to the present invention, can be used advantageously with a plug detecting unit that comprises a switch actuated by the mating of the two connectors, thereby altering a current path for the test signal. Alternatively, the plug detecting unit may also comprise at least two electric contacts which are short circuited by the mating connector in the mated state.

### BRIEF DESCRIPTION OF THE DRAWINGS

The accompanying drawings are incorporated into and form a part of the specification to illustrate several embodiments of the present invention. These drawings, together with a description, serve to explain the principles of the invention. The drawings are merely for the purpose of illustrating the preferred and alternative examples of how the invention can be made and used, and are not to be construed as limiting the invention to only the illustrated and described embodiments. Furthermore, several aspects of the embodiments may form—individually or in different combinations—solutions according to the present invention. Further features and advantages will be become apparent from the following more particular description of the various embodiments of the invention as illustrated in the accompanying drawings, in which like references refer to like elements, and wherein:

FIG. 1 shows a schematic representation of a connector system according to the present invention;

FIG. 2 shows the arrangement of FIG. 1 after the mating connector was inserted;

FIG. 3 shows the mated state of a connector assembly according to a further advantageous embodiment.

### DETAILED DESCRIPTION

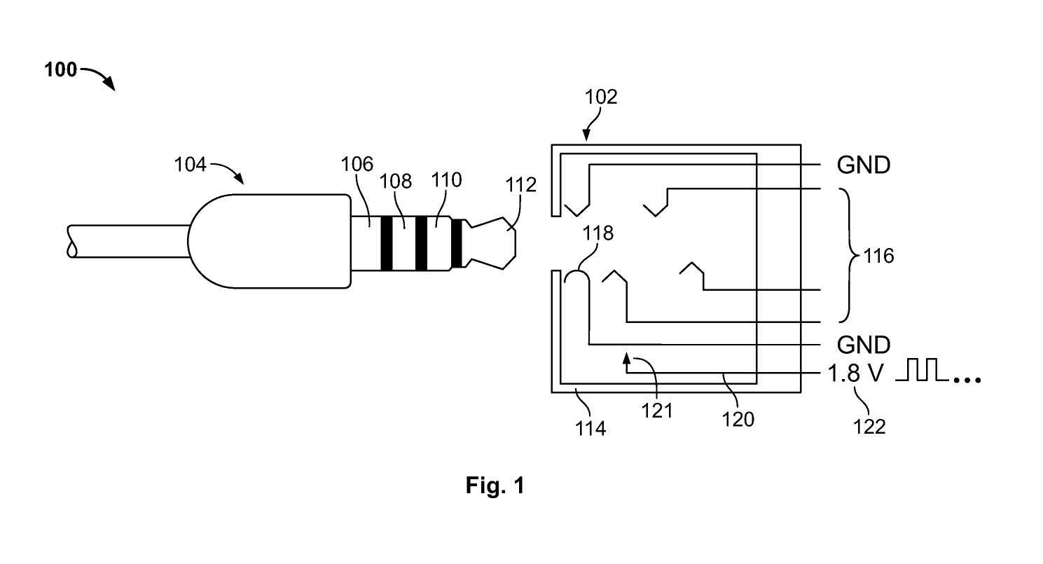

FIG. 1 shows an example of an audio/video connector system 100 comprising a connector 102 and a mating connector 104. In the present example the connector is an audio/video jack and the mating connector 104 is formed by an AV plug that is often called “round standard connector”, “phone plug” or “TRRS connector” (Tip, Ring, Ring, Sleeve connector).

However, the principles of the present invention may, of course, be used for any kind of connector system where the insertion of a mating connector 104 into a connector is detected.

In the present embodiment the insertion of the mating connector 104 is detected at the side of the connector jack 102 by a detecting unit, more precisely, by a plug detecting unit, as will be described below. However, the detecting unit must not necessarily be part of the connector jack, but can also be associated with the plug, then being a “jack detecting unit”. At least a part of the plug detecting unit may be located in an ASIC (application specific integrated circuit) which is arranged on a circuit carrier, such as a printed circuit board, within the device where the connector 102 is built in.

Generally, standardized AV plugs and jacks are frequently used in consumer audio and telecommunication products. AV plugs are familiar to most people with a typical AV plug 104 comprising several cylindrical segments ending in a tip segment. More particularly, the body of the plug 104 usually includes a sleeve 106, one or more rings 108, 110 and a tip 112, each providing contact points with the jack 102. These plug contacts are also often referred to as poles.

According to the present invention, the AV jack 102 is arranged in a sealing housing 114 which blocks the ingress of humidity and debris into the device itself. In order to prevent damages due to humidity, during a standby mode, according to the present invention, all contacts 116 of the AV jack 102 are disconnected from any voltages, such as audio and/or video signals.

A plug detecting unit according to the present invention comprises a plug detecting contact 118 which is movable upon insertion of the plug 104. Preferably, the plug detecting contact 118 is connected to ground (GND).

In addition, the plug detecting unit comprises a switch contact 120 that is connected to a test signal 122. When the plug 104 is inserted into the connector jack 102, the plug detecting contact 118 actuates a switch portion 121 of the switch contact 120, thereby, a circuit between ground and the test signal 122 is closed.

According to the present invention, the test signal 122 is not formed by a continuous positive or negative voltage, but by an intermittent signal. For instance, the test signal 122 may comprise a square wave pulse signal with an amplitude and/or pulse width that are selected so as to minimize the effects of corrosion. In the illustrated example, the square wave pulse signal is formed of 1.8 V pulses having a duration of one microsecond, at one second intervals. Although by the signaling scheme a dead time of one second may occur until the device senses that the plug has been inserted, this delay will not be perceived by a user, whereas the corrosion rate can be reduced by a factor of one thousand.

Alternatively, or in combination with the pulsed signaling, the materials of the switch contact 120 and the moving plug detecting contact 118 may be chosen in a way that the contact carrying the positive signal voltage is fabricated with a surface consisting of the more noble material, that is, the material having a higher oxidation potential. For instance, in the present case, the switch contact 120 may be covered with a gold layer, whereas the contact 118 which is connected to ground is covered with a nickel layer or is fabricated from nickel.

By this measure, the corrosion rate can be significantly decreased.

Upon insertion of the plug 104 and detection of the inserted plug, the standby mode of the device is interrupted and the required signals are applied to the contacts 116. These may be an audio and/or a video signal and, furthermore, may be dependent on the particular kind of plug connector 104, as this is well known in the art.

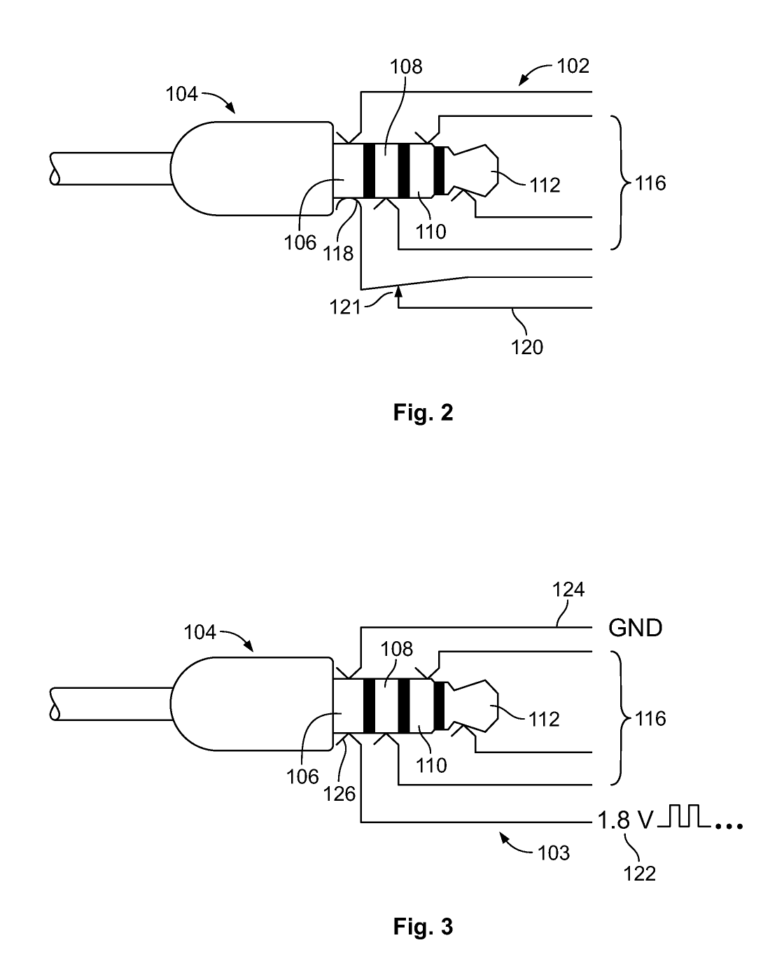

FIG. 2 shows the mated state of the connector 102 and the mating connector 104 according to FIG. 1. For simplicity reasons, the sealing housing 114 of the connector 102 is not illustrated in FIG. 2.

According to an alternative embodiment, the mechanical switch 120 may be replaced by two plug detecting contacts which are short circuited by the sleeve 106 of the mating connector 104 when in the mating state.

FIG. 3 shows the mated state of a connector assembly according to this embodiment, in which the mating connector 104 is inserted into a jack connector 103 having two plug detecting contacts 124, 126 as described above. Similarly to the previous embodiment, the jack connector 103 may comprise a sealing housing (not shown).

In this case, one of the plug detecting contacts 126 is connected to the test signal 122 and the other plug detecting contact 124 is connected to ground (GND).

Again, the plug detection contact 126 can be formed with a surface having a higher oxidation potential than the oxidation potential at a surface of the ground contact 124.

Of course, the principles of the present invention are not restricted to a potential difference between a positive voltage and ground, but may, of course, also be applied to a difference between ground and a negative potential wherein, again, the more positive contact is provided with the more noble metal coating.

The jack contacts 116 and the switch 120 are located in a chamber which is open to the outside and can be wetted by fluids. The chamber itself is sealed towards the inside of the (mobile) device. The normally-open switch 120 has a voltage difference in order to perform the plug detection. According to the present invention, the total time duration of this voltage difference is reduced by employing a short pulse test signal for the plug sensing. When the plug is inserted, the plug detection contact is mated to ground in a mated condition.

Alternatively, the plug detection can be done without a switch by using two jack contacts per plug contact which are short circuited upon insertion of the plug. As will be apparent for those skilled in the art, any of the contacts of the plug (sleeve, first and second ring or tip) may be used for this plug detecting scheme.

For instance, some OEMs use the first ring next to the sleeve for ground and not the sleeve itself. In this case, the first ring may be used as the ground contact for any of the plug detection schemes described above.

Reference Numerals

| Reference | |
|---|---|
| Numerals | Description |
| 100 | connector system |
| 102 | connector (AV jack) in FIGS. 1, 2 |
| 103 | connector (AV jack) in FIG. 3 |
| 104 | mating connector (AV plug) |
| 106 | sleeve |
| 108 | first ring |
| 110 | second ring |
| 112 | tip |
| 114 | housing of the AV jack |
| 116 | contacts of the AV jack |
| 118 | plug detecting contact in FIG. 2 |
| 120 | switch contact of the plug detecting unit |
| 121 | switch portion of switch contact |
| 122 | test signal |
| 124, 126 | Plug detecting contacts in FIG. 3 |
| | GND (ground) contact and test signal contact |

1. Electrical connector with at least one electrical contact for electrically contacting a corresponding mating connector, said connector comprising a plug detecting unit for detecting a mated state of the connector and the mating connector, wherein said plug detecting unit is operable to check the mated state by means of an intermittent test signal.

2. Electrical connector according to claim 1, wherein said intermittent test signal comprises a voltage pulse having the form of a square-wave signal or a sawtooth-signal.

3. Electrical connector according to claim 1, wherein said intermittent test signal has positive and/or negative polarity.

4. Electrical connector according to claim 1, wherein said intermittent test signal comprises HIGH potential phases and LOW potential phases, said HIGH potential phases having a shorter duration than said LOW potential phases.

5. Electrical connector according to claim 1, wherein at least two electrical contacts are provided which are covered with materials having different oxidation potential, wherein a positive voltage is applied to the electrical contact having the higher oxidation potential compared to the other electrical contact.

6. Electrical connector with at least one first electrical contact for electrically contacting a corresponding mating connector, said connector comprising a plug detecting unit for detecting a mated state of the connector and the mating connector, wherein said plug detecting unit comprises a second electrical contact that is operable to check the mated state by means of a test signal, wherein the surfaces of said first and second electrical contacts are covered with materials having a different oxidation potential, and wherein a positive voltage of said test signal is applied to the electrical contact having the higher oxidation potential compared to the other electrical contact.

7. Electrical connector according to claim 6, wherein said plug detecting unit comprises a switch that is actuated by the mating of the two connectors, thereby altering a current path for the test signal.

8. Electrical connector according to claim 6, wherein said plug detecting unit comprises at least two electric contacts which are short-circuited by the mating connector in the mated state, thereby altering a current path for the test signal.

9. Electrical connector according to claim 6, wherein said connector is an Audio/Video jack for a mobile phone.

10. Electrical connector according to claim 6, wherein said connector is embedded in a housing that is sealed against intrusion of water.

11. Electrical connector according to claim 6, wherein said plug detecting unit is operable to change an operating condition of the connector from a stand-by modus into an in-service modus, upon detection of the mated state with the mating connector.

12. Electrical connector according to claim 11, wherein in said stand-by modus apart from the test signal electric potentials are applied to the at least one electrical contact.

13. Method for detecting a mated state of an electrical connector with at least one electrical contact for electrically contacting a corresponding mating connector, said method comprising the steps of:
applying a test signal to a plug detecting circuit which upon insertion of said mating connector is closed to indicate said mated state, wherein said test signal is an intermittent signal.

14. Method according to claim 13, wherein said intermittent test signal comprises a voltage pulse having the form of a square-wave signal or a sawtooth-signal.

15. Method according to claim 13, wherein said intermittent test signal has positive and/or negative polarity.

16. Electrical connector according to claim 13, wherein said intermittent test signal comprises HIGH potential phases and LOW potential phases, said HIGH potential phases having a shorter duration than said LOW potential phases.
